(19) United States
(12) Patent Application Publication
(10) Pub. No.: US 2022/0375831 A1
(43) Pub. Date: Nov. 24, 2022

(54) LEAD FRAME, AND SEMICONDUCTOR DEVICE

(71) Applicant: SHINKO ELECTRIC INDUSTRIES CO., LTD., Nagano-shi (JP)

(72) Inventors: Tetsuichiro Kasahara, Nagano (JP); Tsukasa Nakanishi, Nagano (JP); Koji Watanabe, Nagano (JP); Jun Izuoka, Nagano (JP)

(21) Appl. No.: 17/749,774

(22) Filed: May 20, 2022

(30) Foreign Application Priority Data
May 24, 2021 (JP) 2021-087209

(51) Int. Cl. H01L 23/495; H01L 23/31

(52) U.S. Cl. CPC H01L 23/49503; H01L 23/3107; H01L 23/4952; H01L 23/49558

(57) ABSTRACT

A lead frame includes a first frame member including a die pad; a second frame member that is layered on the first frame member and that includes a lead; and a resin with which a space around the die pad and the lead is filled, wherein the die pad includes a rising portion and a buried portion, the rising portion rises from the resin, the buried portion is buried in the resin and has a mount surface on which a semiconductor element is to be mounted and a side surface that is continuous to the mount surface, and the side surface is covered with the resin and has a constriction that is depressed in a direction parallel to the mount surface.

### CROSS-REFERENCE TO RELATED APPLICATION

This application is based upon and claims the benefit of priority of the prior Japanese Patent Application No. 2021-087209, filed on May 24, 2021, the entire contents of which are incorporated herein by reference.

### FIELD

The embodiments discussed herein are related to a lead frame, a semiconductor device and a method of manufacturing the lead frame.

### BACKGROUND

In recent years, semiconductor devices in which a semiconductor element, such as an integrated circuit (IC) chip, is mounted on a lead frame made of metal have been known. In other words, for example, a semiconductor element is mounted on a planar die pad that is provided at the center of a lead frame and the semiconductor element is connected by wire bonding to a plurality of leads that are provided around the die pad. The semiconductor element that is mounted on the lead frame is sometimes sealed with a resin, such as epoxy resin, to form a semiconductor device.

Such lead frames include one having a bilayer structure obtained by layering two frame members. In other words, the lead frame having the bilayer structure is structured by layering a frame member with leads on a frame member with a die pad. The space between the die pad and the leads is filled with, for example, resin. Accordingly, because the two frames are reinforced by the resin, it is possible to increase the strength of the entire lead frame.
Patent Literature 1: Japanese Laid-open Patent Publication No. 2017-130493

The lead frame having the bilayer structure has a problem in that there is a risk that the die pad would separate from the resin. In other words, because a portion of the die pad corresponding to a half of the thickness of the whole die pad is buried in the resin and the portion corresponding to the remaining half rises from the resin, the die pad makes contact with the sealing resin on only side surfaces of the portion that is buried in the resin. In a surface area of the die pad, however, the area occupied by the side surfaces of the portion buried in the resin is small and adherence between the die pad and the resin is not so high. For this reason, for example, when deformation, such as warping, occurs in the lead frame, there is a risk that the die pad would separate from the resin easily because of application of a stress due to the deformation to the border between the die pad and the resin.

### SUMMARY

According to an aspect of an embodiment, a lead frame includes a first frame member including a die pad; a second frame member that is layered on the first frame member and that includes a lead; and a resin with which a space around the die pad and the lead is filled, wherein the die pad includes a rising portion and a buried portion, the rising portion rises from the resin, the buried portion is buried in the resin and has a mount surface on which a semiconductor element is to be mounted and a side surface that is continuous to the mount surface, and the side surface is covered with the resin and has a constriction that is depressed in a direction parallel to the mount surface.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating an example of a configuration of a lead frame according to a first embodiment;

FIG. 2 is a flowchart illustrating an example of a method of manufacturing the lead frame according to the first embodiment;

FIG. 3 is a diagram illustrating a specific example of a first frame member molding step;

FIG. 4 is a diagram illustrating a specific example of a second frame member molding step;

FIG. 5 is a diagram illustrating a specific example of a frame member layering step;

FIG. 6 is a diagram illustrating a specific example of a resin sealing step;

FIG. 7 is a diagram illustrating a specific example of an etching resist forming step;

FIG. 8 is a diagram illustrating a specific example of an etching step;

FIG. 9 is a diagram illustrating a specific example of an etching resist removing step;

FIG. 10 is a diagram illustrating a specific example of an electrolytic plating step;

FIG. 11 is a diagram illustrating mounting of a semiconductor element;

FIG. 12 is a diagram illustrating wire bonding;

FIG. 13 is a diagram illustrating a mold;

FIG. 14 is a diagram illustrating an example of a configuration of a semiconductor device;

FIG. 15 is a cross-sectional view illustrating an example of a configuration of a lead frame according to a second embodiment;

FIG. 16 is a diagram illustrating a specific example of an etching resist forming step;

FIG. 17 is a diagram illustrating a specific example of an etching step;

FIG. 18 is a diagram illustrating wire bonding; and

FIG. 19 is a diagram illustrating an example of a first frame member and a second frame member on which etching resists are formed.

### DESCRIPTION OF EMBODIMENTS

Embodiments of a lead frame, a semiconductor device and a method of manufacturing the lead frame disclosed herein will be described in detail below according to the accompanying drawings. The embodiments do not limited the disclosed technique.

### First Embodiment

Configuration of Lead Frame

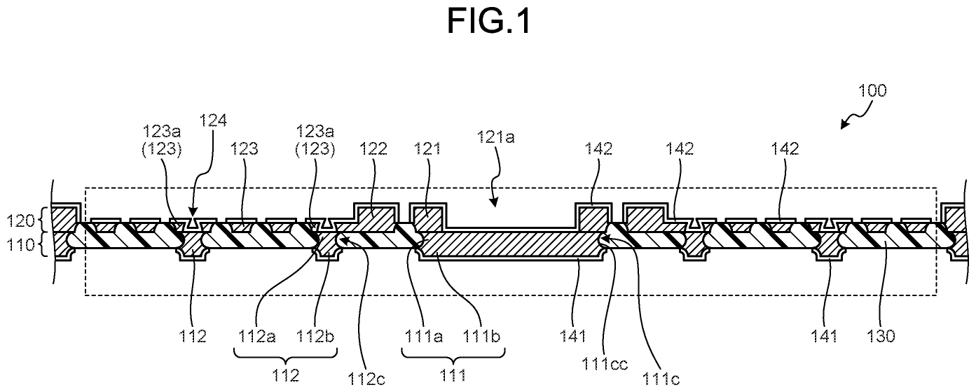

FIG. 1 is a diagram illustrating an example of a configuration of a lead frame 100 according to a first embodiment. FIG. 1 schematically illustrates a cross-section of the lead frame 100. The lead frame 100 illustrated in FIG. 1 is manufactured as an assembly obtained by, for example, arraying units surrounded by the dotted line repeatedly in a horizontal direction and a depth direction. The unit surrounded by the dotted line is a unit that is separated as an individual semiconductor device after a semiconductor element is mounted on the lead frame 100 and is sealed with resin. The embodiment will be described below using the unit surrounded by the dotted line as the example of the lead frame 100. The number of the units surrounded by the dotted line is not particularly limited.

In the following description, the surface of the lead frame 100 on which the semiconductor element is mounted is described as a surface on an upper side (upper surface); however, the lead frame 100 may be manufactured and used flip vertically or may be manufactured and used in a given posture.

The lead frame 100 has a bilayer structure obtained by layering a first frame member 110 and a second frame member 120. Each element that the first frame member 110 includes and each element that the second frame member 120 includes are sealed with a resin 130.

The first frame member 110 is a plate member that is made of metal and on which a semiconductor element is mounted and is a member on which an external connection terminal that electrically connects the lead frame 100 to an external part is formed. For example, copper or copper alloy and steel-nickel alloy, such as 42 alloy, are usable as a material of the first frame member 110. The thickness of the first frame member 110 can be set, for example, at approximately 0.1 mm to 0.3 mm.

The first frame member 110 includes a die pad 111 and a plurality of terminals 112.

The die pad 111 is a platy area on which the first frame member 110 is formed at the center. An upper surface of the die pad 111 is a mount surface on which the semiconductor element is mounted. For this reason, the upper surface of the die pad 111 is not covered with the resin 130. The die pad 111 includes a buried portion 111a whose side surfaces continuous to the upper surface (in other words, a mount surface) are covered with the resin 130 and a rising portion 111b rising from a lower surface of the resin 130. Each of the buried portion 111a and the rising portion 111b has a thickness that is approximately a half of the thickness of the whole die pad 111. A constriction 111c that is depressed in a direction parallel to the upper surface of the buried portion 111a (in other words, the mount surface) is formed on the side surfaces of the buried portion 111a.

The terminals 112 are arranged around the die pad 111 and are used as external connection terminals that electrically connect the lead frame 100 to the external part. Upper surfaces of the terminals 112 and the upper surface of the die pad 111 are positioned within the same plane and lower surfaces of the terminals 112 and a lower surface of the die pad 111 are positioned within the same plane. In other words, the terminals 112 and the die pad 111 have equal thicknesses. The terminal 112 includes a buried portion 112a that is positioned in the resin 130 and a rising portion 112b that rises from the lower surface of the resin 130. Each of the buried portion 112a and the rising portion 112b has a thickness that is approximately a half of the thickness of the whole die pad 111. Side surfaces of the buried portion 112a are covered with the resin 130. On the side surfaces of the buried portion 112a, a constriction 112c that is depressed in a direction parallel to an upper surface of the buried portion 112a is formed.

The second frame member 120 is a platy member made of metal that grounds the semiconductor element that is mounted on the upper surface of the die pad 111 and is a member on which a circuit pattern that connects the semiconductor element and the terminals 112 that are external connection terminals is formed. For example, coper or copper alloy and steel-nickel alloy, such as 42 alloy, are usable as a material of the second frame member 120. The thickness of the second frame member 120 can be, for example, approximately 0.1 to 0.3 mm.

The second frame member 120 includes a ground pad 121, a plurality of leads 122, and a plurality of interconnects 123.

The ground pad 121 is a pad that, when the semiconductor element is mounted on the upper surface of the die pad 111, electrically connects the semiconductor element to the die pad 111 to ground the semiconductor element. The ground pad 121 is arranged along the circumference of the upper surface of the die pad 111 and has, at the center, an opening 121a that exposes the upper surface of the die pad 111. A lower end of the ground pad 121 is positioned in the resin 130 and an upper end of the ground pad 121 rises from an upper surface of the resin 130. When the semiconductor element is mounted on the upper surface of the die pad 111, the semiconductor element is connected to the ground pad 121 by wire bonding.

The leads 122 are terminals that, when the semiconductor element is mounted on the upper surface of the die pad 111, electrically connect the semiconductor element to the terminals 112 that are external connection terminals via the interconnects 123. The leads 122 are arranged around the ground pad 121. Lower ends of the leads 122 are positioned in the resin 130 and upper ends of the leads 122 rise from the upper surface of the resin 130. Upper-end end faces of the leads 122 are positioned within the same plane as that of an upper-end end face of the ground pad 121 and lower-end end faces of the leads 122 are positioned within the same plane as lower-end end faces of the ground pad 121. In other words, the lead 122 and the ground pad 121 have the same thickness. When the semiconductor element is mounted on the upper surface of the die pad 111, the semiconductor element is connected to the leads 122 by wire bonding.

The interconnects 123 are positioned in the resin 130 with their upper surfaces being exposed from the upper surface of the resin 130. The interconnects 123 stretch in a form of a predetermined pattern in the resin 130 and, at their ends, are electrically connected to the leads 122. The interconnects 123 correspond to the terminals 112 of the first frame member 110 one-on-one and pass through positions overlapping the terminals 112 in a planar view. In the position in which the interconnect 123 overlaps the terminal 112 in the planar view, an interlayer connector 123a is formed. The interlayer connector 123a has a discoid shape with a diameter larger than a width of other portions of the interconnect 123 and electrically connects the interconnect 123 to the terminal 112. In other words, an opening 124 that penetrates to the upper surface of the terminal 112 (buried portion 112a) is formed at the center of the interlayer connector 123a. An upper surface of the interlayer connector 123a, an inner wall surface of the opening 124, and the upper surface of the terminal 112 that is exposed from the opening 124 are coated with a plating layer 142 to be described below, so that the interconnect 123 and the terminal 112 are electrically connected via the interlayer connector 123a and the plating layer 142. Accordingly, the interconnects 123 and the leads 122 form the circuit pattern that connect the semiconductor element that is mounted on the upper surface of the die pad 111 and the terminals 112 that are the external connection terminals.

Each element that the first frame member 110 includes and each element that the second frame member 120 includes are sealed with the resin 130. In other words, the space around the die pad 111, the terminals 112, the ground pad 121, the leads 122 and the interconnects 123 is filled with the resin 130. For example, an insulating resin, such as polyimide resin or epoxy resin, or a resin material obtained by mixing fillers, such as silica or aluminum, into such resin is usable as the material of the resin 130.

Plating layers are formed on the surfaces of the first frame member 110 and the second frame member 120 that are not covered with the resin 130 and are exposed. For example, a plating layer 141 is formed on a lower surface of the rising portion 111b and side surfaces of the rising portion 111b in the die pad 111 and a lower surface of the rising portion 112b and side surfaces of the rising portion 112b in the terminal 112. The plating layer 142 is formed on upper-end side surfaces of the ground pad 121, the upper-end end face of the ground pad 121, an inner wall surface of the opening 121a, the upper surface of the die pad 111 that is exposed from the opening 121a, the upper-end end face of the lead 122, upper-end side surfaces of the lead 122, and an upper surface of the interconnect 123. The plating layer 142 that is formed on the upper surface of the interconnect 123 convers the upper surface of the interlayer connector 123a, the inner wall surface of the opening 124, and the upper surface of the terminal 112 that is exposed from the opening 124.

The lead frame 100 that has the bilayer structure consisting of the first frame member 110 and the second frame member 120 has a possibility that the die pad 111 would separate from the resin 130. In other words, in the lead frame 100 having the bilayer structure, the buried portion 11a corresponding to the half of the thickness of the whole die pad 111 is buried in the resin 130 and the rising portion 111b corresponding to the remaining half rises from the resin 130. Thus, the die pad 111 makes contact with the resin 130 on only the side surfaces of the buried portion 111a and the area of contact with the resin 130 is not so large. As a result, there is a possibility that the die pad 111 would separate from the resin 130.

Thus, in the lead frame 100 according to the embodiment, as illustrated in FIG. 1, the constriction 111c is formed on the side surfaces of the buried portion 111a of the die pad 111. A bottom portion 111cc of the constriction 111c is in a more inner position in the buried portion 111a than the circumference of the upper surface of the buried portion 111a (that is, the mount surface). The bottom portion 111cc of the constriction 111c denotes a portion at which the depth of the constriction 111c is the largest.

The constriction 111c is formed in the side surfaces of the buried portion 111a and accordingly the constriction 111c is filled with the resin 130 and therefore adherence between the die pad 111 and the resin 130 can be increased by the anchor effect. As a result, it is possible to inhibit the die pad 111 from separating from the resin 130.

Furthermore, because the bottom portion 111cc of the constriction 111c is in the more inner position in the buried portion 111a than the circumference of the upper surface of the buried portion 111a, it is possible to increase adherence between the die pad 111 and the resin 130 and thus it is possible to further reduce the possibility of separation of the die pad 111.

In the lead frame 100 having the bilayer structure, like the die pad 111, the terminal 112 makes contact with the resin 130 on only the side surfaces of the buried portion 112a and the area of contact with the resin 130 is not so large. To deal with this, in the lead frame 100, as illustrated in FIG. 1, the constriction 112c is formed on the side surfaces of the buried portion 112a of the terminal 112. This makes it possible to increase adherence between the terminal 112 and the resin 130. As a result, it is possible to inhibit the terminal 112 from separating from the resin 130.

Method of Manufacturing Lead Frame

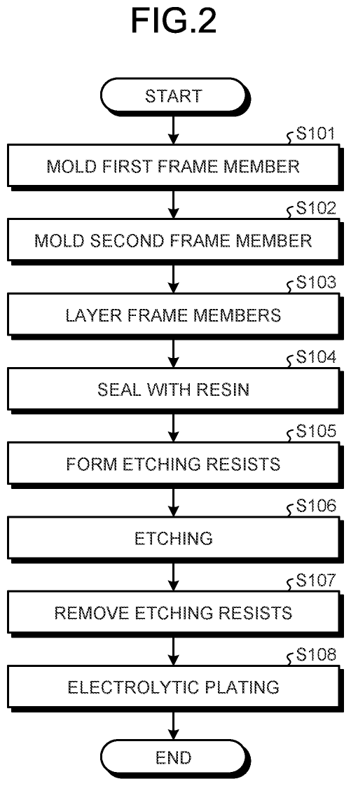

With reference to FIG. 2, a method of manufacturing the lead frame 100 configured as described above will be described specifically, taking an example. FIG. 2 is a flowchart illustrating an example of the method of manufacturing the lead frame 100 according to the first embodiment.

First of all, the first frame member 110 and the second frame member 120 serving as frames of the lead frame 100 are molded (steps S101 and S102). Each of the first frame member 110 and the second frame member 120 is molded by etching a metal plate.

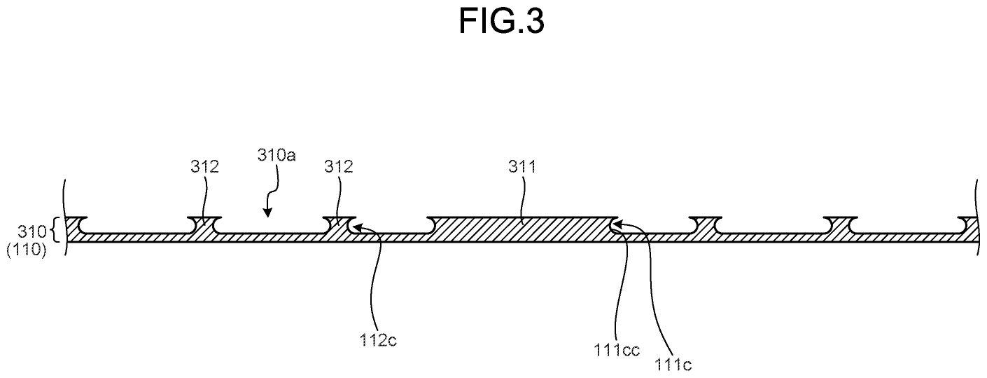

Specifically, for example, as illustrated in FIG. 3, a first metal plate 310 is dissolved by half etching from an upper surface of the first metal plate 310 such that a base 311 and a plurality of protrusions 312 that are arranged around the base 311 are left. FIG. 3 is a diagram illustrating a specific example of a first frame member molding step. A first depressed portion 310a is formed around the base 311 and the protrusions 312 that remain. In other words, the first frame member 110 in which the base 311 and the protrusions 312 are sectioned by the first depressed portion 310a is molded from the first metal plate 310.

An anisotropic etching solution is used to etch the first metal plate 310. In other words, anisotropic etching using the anisotropic etching solution is performed on the first metal plate 310 when the first frame member 110 is molded and accordingly dissolving of the base 311 progresses not only in the direction of the thickness of the first metal plate 310 but also in the direction of the plane. Accordingly, the base 311 with the constriction 111c that is depressed in a direction parallel to the upper surface in the side surface is formed in the first frame member 110. The base 311 is formed such that the bottom portion 111cc of the constriction 111c is in a more inner position in the base 311 than the circumference of an upper surface of the base 311. Anisotropic etching is performed on the first metal plate 310 and thus, as in the base 311, dissolving of the protrusion 312 progresses not only in the thickness direction of the first metal plate 310 but also in the plane direction. Accordingly, in the first frame member 110, the protrusion 312 having the constriction 112c that is depressed in a direction parallel to the upper surface is formed in side surfaces in the first frame member 110. The protrusion 312 is formed such that the bottom portion of the constriction 112c is in a more inner position in the protrusion 312 than the circumference of an upper surface of the protrusion 312.

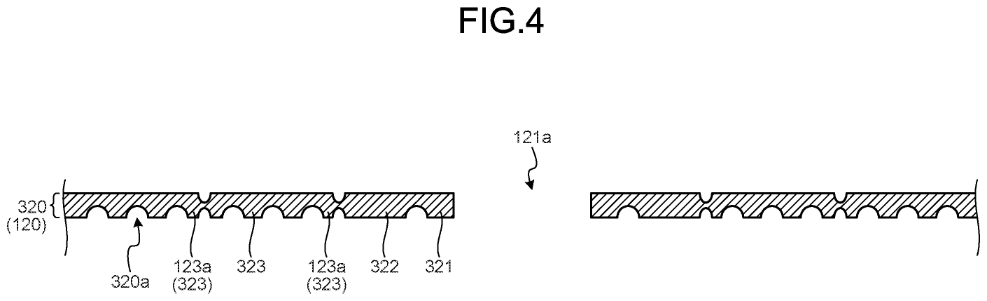

For example, as illustrated in FIG. 4, a second metal plate 320 is dissolved by half etching from a lower surface of the second metal plate 320 such that a base 321, and a plurality of protrusions 322 and a plurality of protrusions 323 that are arranged around the base 321 are left. FIG. 4 is a diagram illustrating a specific example of a second frame member molding step. A second depressed portion 320a is formed around the base 321, the protrusions 322 and the protrusions 323 that remain. In other words, the second frame member 120 in which the base 321, the protrusions 322, and the protrusions 323 are sectioned by the second depressed portion 320a is molded from the second metal plate 320.

The protrusions 323 stretch in a form of a predetermined pattern along a direction of a plane of a second metal plate 320 and, at their ends, are connected to the protrusions 322 as appropriate. The interlayer connector 123a is formed in a predetermined position in a direction in which the protrusion 323 extends. By half etching on the second metal plate 320, depressed portions that do no communicate are formed on both end faces of the interlayer connector 123a. Half etching from both surfaces of the second metal plate 320 forms the opening 121a at the center of the base 321.

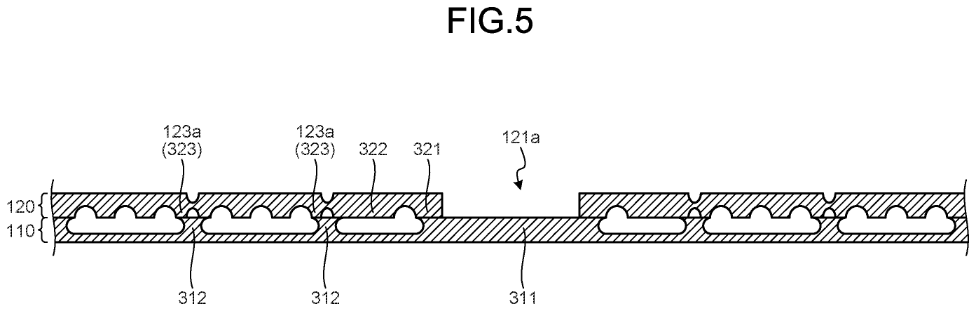

After the first frame member 110 and the second frame member 120 are molded by etching the metal plates, the second frame member 120 is layered on the first frame member 110 (step S103). Specifically, the second frame member 120 is layered on the first frame member 110 such that the base 321 is arranged along the circumference of the upper surface of the base 311 and the interlayer connector 123a of the protrusion 323 makes contact with the upper surface of the protrusion 312. Accordingly, for example, as illustrated in FIG. 5, the intermediate structure having the bilayer structure consisting of the first frame member 110 and the second frame member 120 is formed. The first depressed portion 310a and the second depressed portion 320a form a space around the base 311, the protrusions 312, the base 321, the protrusions 322 and the protrusion 323 of the intermediate structure. The upper surface of the base 311 is exposed in the opening 121a of the base 321. FIG. 5 is a diagram illustrating a specific example of a frame member layering step.

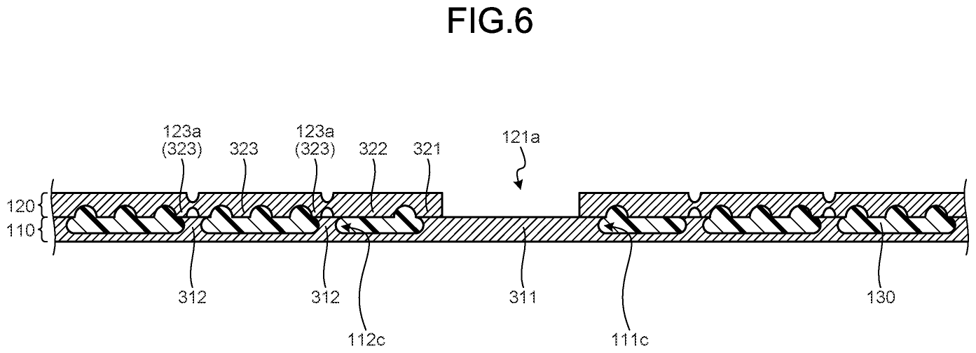

The intermediate structure is sealed with resin by, for example, transfer molding (step S104). In other words, the intermediate structure is set in a cavity of a metal mold and the resin 130 that is uncured is injected into the cavity of the metal mold and thereafter the resin 130 is heated and cured. Instead of the transfer molding, for example, compression molding or injection molding may be used as a method of sealing with resin. Sealing the intermediate structure with resin fills the space around the base 311, the protrusions 312, the base 321, the protrusions 322 and the protrusions 323. The constriction 111c is formed in the side surfaces of the base 311 and accordingly the resin 130 is supplied also to the constriction 111c and accordingly adherence between the base 311 and the resin 130 increases. Furthermore, the constriction 112c is formed on the side surfaces of the protrusion 312 and accordingly the resin 130 is supplied also to the constriction 112c and adherence between the protrusions 312 and the resin 130 increases. FIG. 6 is a diagram illustrating a specific example of a resin sealing step.

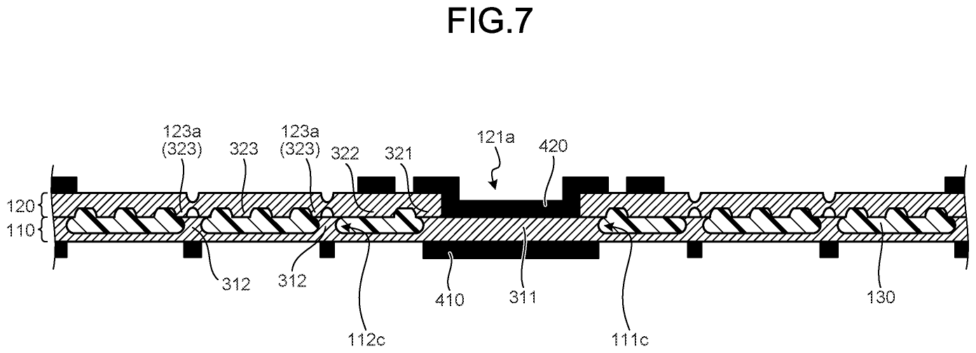

After the intermediate structure is sealed, an etching resist is formed on each of the surfaces of the first frame member 110 and the second frame member 120 (step S105). Specifically, for example, as illustrated in FIG. 7, an etching resist 410 is formed on a side of a lower surface of the first frame member 110 and an etching resist 420 is formed on a side of an upper surface of the second frame member 120. FIG. 7 is a diagram illustrating a specific example of an etching resist forming step. The etching resists 410 and 420 are formed in positions to be left as the die pad 111, the terminals 112, the ground pad 121 and the leads 122. For example, the etching resist 410 is formed in the positions of the base 311 and the protrusions 312 to be left as the die pad 111 and the terminals 112, respectively. For example, the etching resist 420 is formed in the positions of the base 321 and the protrusions 322 to be left as the ground pad 121 and the leads 122, respectively. For example, the etching resist 420 is also formed in the positions of the inner wall surface of the opening 121a and the upper surface of the base 311 that is exposed in the opening 121a. Note that etching resists gaps are formed in given portions not overlapping the base 311, the protrusions 312, the base 321 and the protrusions 322 in the etching resists 410 and 420.

The first frame member 110 and the second frame member 120 on which the above-described etching resists are formed are immersed in an etching solution and are etched (step S106). Specifically, for example, the first frame member 110 and the second frame member 120 are immersed in an etching solution, such as sulfuric-acid hydrogen peroxide or persulfate, and accordingly the given portions that are not covered with the etching resists are dissolved and the frame members are molded into the shape of the lead frame 100.

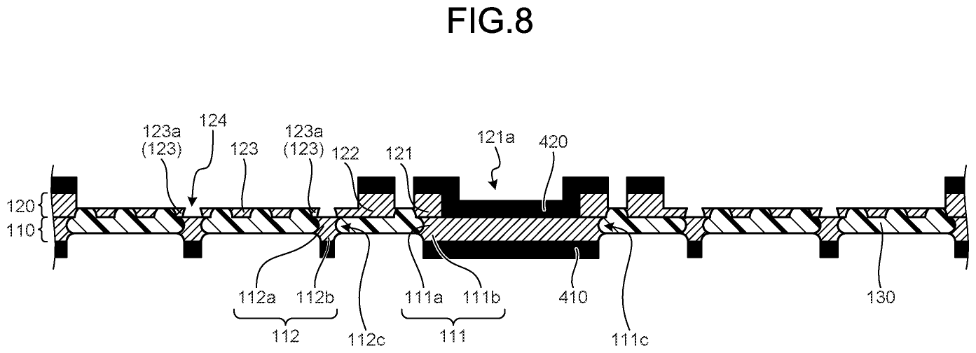

In other words, for example, as illustrated in FIG. 8, the given portions not overlapping the base 311 of the first frame member 110 and the protrusions 312 are etched, so that the die pad 111 and the terminals 112 are formed. Furthermore, for example, the given portions not overlapping the base 321 of the second frame member 120, the upper surface of the base 311 and the protrusions 322 are etched, so that the ground pad 121, the leads 122 and the interconnects 123 are formed. The depressed portions that are formed on both end faces of the interlayer connector 123a of the interconnect 123 communicate by etching from the side of the upper surface of the interlayer connector 123a and accordingly the opening 124 is formed. FIG. 8 is a diagram illustrating a specific example of an etching step.

As described above, etching forms the die pad 111 and the terminals 112 in the first frame member 110 and at the same time forms the ground pad 121, the leads 122 and the interconnects 123 in the second frame member 120. The die pad 111 includes the buried portion 111a whose side surface is covered with the resin 130 and has the constriction 111c and the rising portion 111b that rises from the resin 130. The terminal 112 includes the buried portion 112a that is positioned in the resin 130 and that has the constriction 112c on the side surface and the rising portion 112b that rises from the lower surface of the resin 130. In the second frame member 120, the opening 124 is formed in the interlayer connector 123a by performing etching enabling communication between the depressed portions that are formed on both the end faces of the interlayer connector 123a of the interconnect 123.

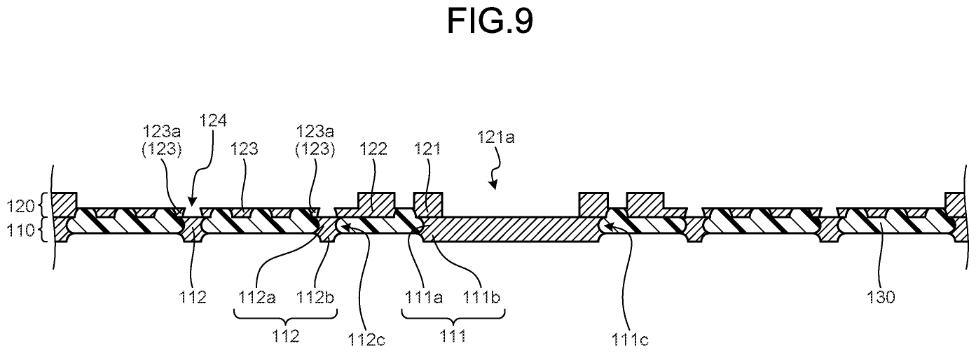

After the etching completes, the etching resists 410 and 420 are removed using, for example, an amine or non-amine removal solution (step S107) and accordingly the lead frame 100 having the bilayer structure consisting of the first frame member 110 and the second frame member 120 is obtained. In other words, for example, as illustrated in FIG. 9, the lead frame 100 having the bilayer structure obtained by layering the first frame member 110 including the die pad 111 and the terminals 112 and the second frame member 120 including the ground pad 121, the leads 122 and the interconnects 123 is obtained. FIG. 9 is a diagram illustrating a specific example of an etching resist removing step.

Electroplating is performed on the lead frame 100 that is molded (step S108) and the lead frame 100 is completed. Specifically, power is supplied from the side of the first frame member 110 or the side of the second frame member 120, so that a plating layer is formed in metal portions of the first frame member 110 and the second frame member 120 that are not covered with the resin 130.

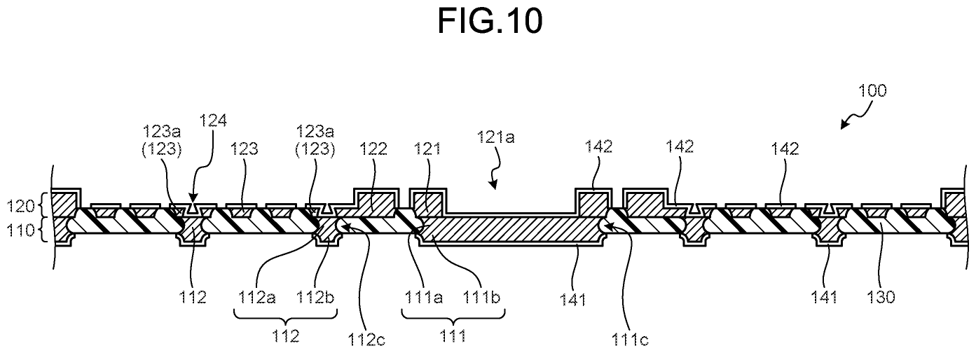

In other words, for example, as illustrated in FIG. 10, the plating layer 141 is formed on the lower surface of the rising portion 111b of the die pad 111, the lower surface of the rising portion 112b of the terminal 112, and the side surfaces of the rising portion 112b. The plating layer 142 is formed on the upper-end side surfaces of the ground pad 121, the upper-end end face of the ground pad 121, the inner wall surface of the opening 121a, the upper surface of the die pad 111 that is exposed from the opening 121a, the upper-end end face of the lead 122, the upper-end side surfaces of the lead 122, and the upper surface of the interconnect 123. The plating layer 142 convers the upper surface of the interlayer connector 123a, the inner wall surface of the opening 124 and the upper surface of the terminal 112 that is exposed from the opening 124 and covers the inner wall surface of the opening 121a and the upper surface of the buried portion 11a that is exposed from the opening 121a. Accordingly, the plating layer 142 enables the interlayer connector 123a to be joined to the terminal 112 and enables the ground pad 121 to be joined to the die pad 111. As a result, the strength of bonding between the interlayer connector 123a and the terminal 112 and the strength of bonding between the ground pad 121 and the die pad 111 increase, which makes it possible to further reduce the possibility that the die pad 111 and the terminals 112 would separate from the resin 130. FIG. 10 is a diagram illustrating a specific example of an electrolytic plating step.

For example, there are Ni (nickel)/Ag (silver), Ni/Pd (paladium)/Au (gold), Sn (tin), Ag, etc., as metal that is used for the plating layers 141 and 142. Ni/Ag is a plating layer obtained by layering an Ni layer and an Ag layer from a lower layer side, Ni/Pd/Au is a plating layer obtained by layering an Ni layer, a Pd layer and an Au layer from the lower layer side. Instead of electrolytic plating, for example, PPF (Pre Plated LeadFrame), or the like, may be used.

The lead frame 100 completed includes the constriction 111c in the side surfaces of the buried portion 111a of the die pad 111. The constriction 111c is formed in the side surfaces of the buried portion 111a and accordingly the constriction 111c is filled with the resin 130 and therefore adherence between the die pad 111 and the resin 130 can be increased by the anchor effect. As a result, it is possible to inhibit the die pad 111 from separating from the resin 130.

Process of Manufacturing Semiconductor Device

A process of manufacturing a semiconductor device by mounting a semiconductor element on the lead frame 100 will be described.

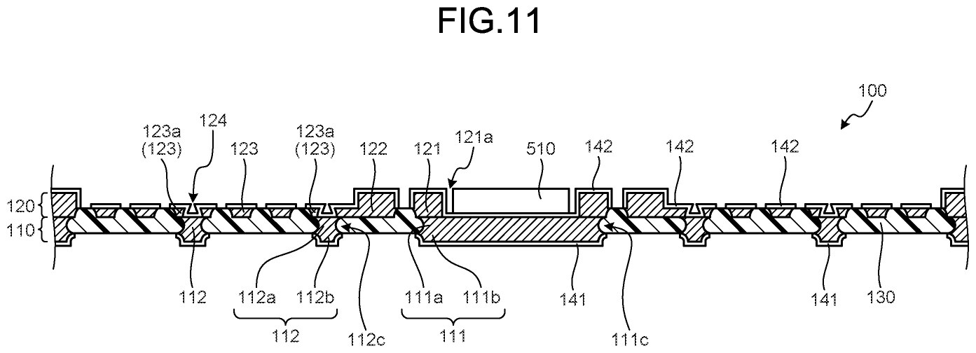

A semiconductor element is mounted on the die pad 111 of the lead frame 100. Specifically, for example, as illustrated in FIG. 11, using a joining material, such as solder or a die attach paste, a semiconductor element 510 is joined to the upper surface of the die pad 111 that is exposed from the opening 121a of the ground pad 121. FIG. 11 is a diagram illustrating mounting of the semiconductor element.

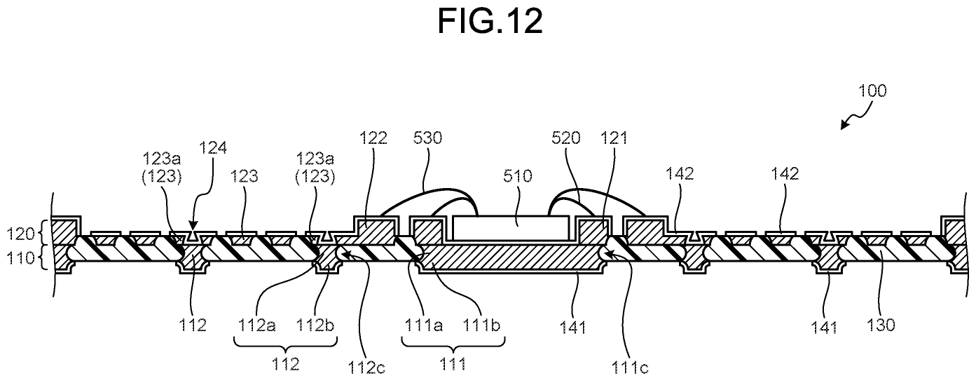

When the semiconductor element 510 is joined to the upper surface of the die pad 111, for example, as illustrated in FIG. 12, the semiconductor element 510 and the ground pad 121 are connected by wire bonding and the semiconductor element 510 and the leads 122 are connected by wire bonding. In other words, a ground electrode of the semiconductor element 510 is electrically connected by a wire 520 to the plating layer 142 on the ground pad 121 and a signal electrode of the semiconductor element 510 is electrically connected by a wire 530 to the plating layer 142 on the lead 122. At that time, because the semiconductor element 510 is mounted on the upper surface of the die pad 111 that is exposed from the opening 121a of the ground pad 121, the level of the upper surface of the semiconductor element 510 is approximately equal to the level of the plating layer 142 on the ground pad 121 and the lead 122. As a result, it is possible to reduce the thickness of the semiconductor device and shorten the lengths of the wires 520 and 530. FIG. 12 is a diagram illustrating wire bonding.

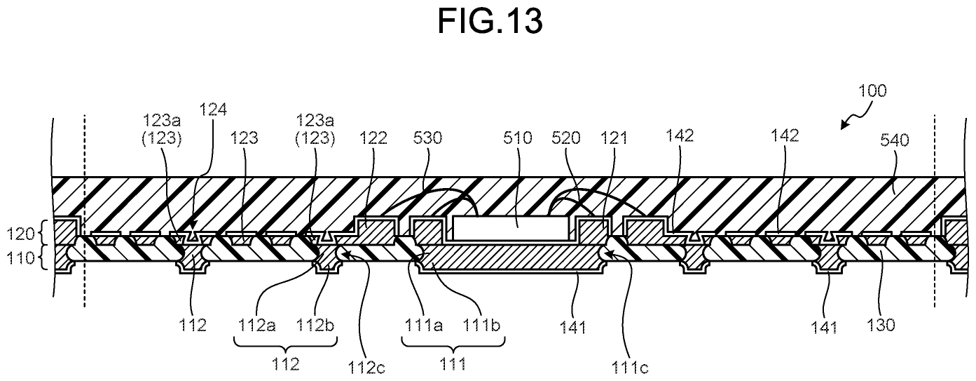

Molding for sealing the semiconductor element 510 that is mounted on the lead frame 100 with a sealing resin is then performed. Specifically, the lead frame 100 on which the semiconductor element 510 is mounted is housed in a metal mold and a fluidized sealing resin is injected into the metal mold. The sealing resin is heated to a given temperature and cures, so that, for example, as illustrated in FIG. 13, the space around the semiconductor element 510 is filled with a sealing resin 540 and the semiconductor element 510 that is mounted on the lead frame 100 is sealed. FIG. 13 is a diagram illustrating a mold.

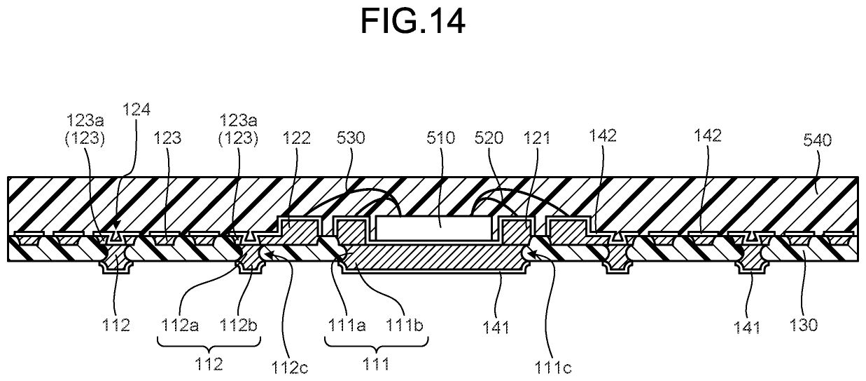

After the semiconductor element 510 that is mounted on the lead frame 100 is sealed with the sealing resin 540, for example, in a dotted-lined portions illustrated in FIG. 13, the sealing resin 540 and the lead frame 100 are cut. Accordingly, the lead frame 100 is separated into pieces and, for example, as illustrated in FIG. 14, a semiconductor device including the die pad 111, the terminals 112, the ground pad 121, the leads 122, the interconnects 123, the semiconductor element 510, and the sealing resin 540 is completed. FIG. 14 is a diagram illustrating an example of a configuration of the semiconductor device.

As described above, a lead frame (for example, the lead frame 100) according to the embodiment includes a first frame member (for example, the first frame member 110), a second frame member (for example, the second frame member 120), and a resin (for example, the resin 130). The first frame member includes a die pad (for example, the die pad 111) having a mount surface on which a semiconductor element (the semiconductor element 510) is to be mounted. The second frame member includes a lead (for example, the lead 122). The space around the die pad and the lead is filled with the resin. The die pad includes a buried portion (for example, the buried portion 111a) and a rising portion (for example, the rising portion 111b). The buried portion is a buried portion whose side surface continuous to the mount surface is covered with the resin and has, on a side surface, a constriction (for example, the constriction 111c) that is depressed in a direction parallel to the mount surface. The rising portion rises from the resin. Accordingly, according to the lead frame according to the embodiment, it is possible to inhibit the die pad from separating from the resin.

A bottom portion (for example, the bottom portion 111cc) according to the embodiment is in a more inner position in the buried portion than the circumference of the mount surface. Thus, according to the lead frame according to the embodiment, it is possible to further reduce a possibility of separation of the die pad.

### Second Embodiment

A second embodiment relates to a variation of the die pad 111 of the first embodiment.

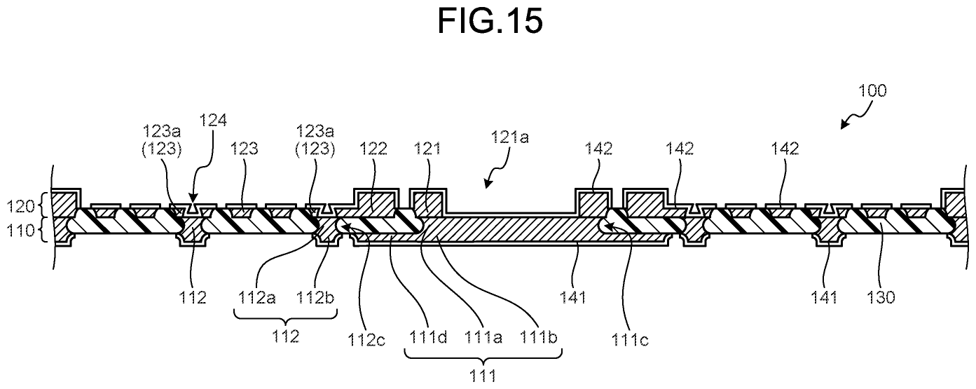

FIG. 15 is a cross-sectional view illustrating an example of a configuration of the lead frame 100 according to the second embodiment. In FIG. 15, the same components as those in FIG. 1 are denoted with the same reference numerals as those in FIG. 1. The die pad 111 illustrated in FIG. 15 includes an extending portion 111d in addition to the buried portion 111a and the rising portion 111b.

The extending portion 111d is formed in a manner that the outer circumference of the rising portion 111b extends in a direction of the terminal 112 along the surface (lower surface) of the resin 130. Specifically, the extending portion 111d extends to a position corresponding to the lead 122 on the surface of the resin 130.

The extending portion 111d reduces a possibility that the die pad 111 would separate from the resin 130. In other words, because forming the extending portion 111d increases the area of contact between the die pad 111 and the resin 130, the strength of bonding between the die pad 111 and the resin 130 increases. Furthermore, extension of the extending portion 111d to a position corresponding to the lead 122 on the surface of the resin 130 increases reliability of connection between the leads 122 and the wires at the time of wire bonding between the leads 122 and the semiconductor element mounted on the upper surface of the die pad 111.

A method of manufacturing the lead frame 100 configured as described above will be described specifically, taking an example. Description of the same steps as those of the first embodiment will be simplified.

First of all, as in the first embodiment, each of the steps from the step of forming the first frame member 110 and the second frame member 120 (steps S101 and S102) to the resin sealing step (step S104) in FIG. 2 is performed.

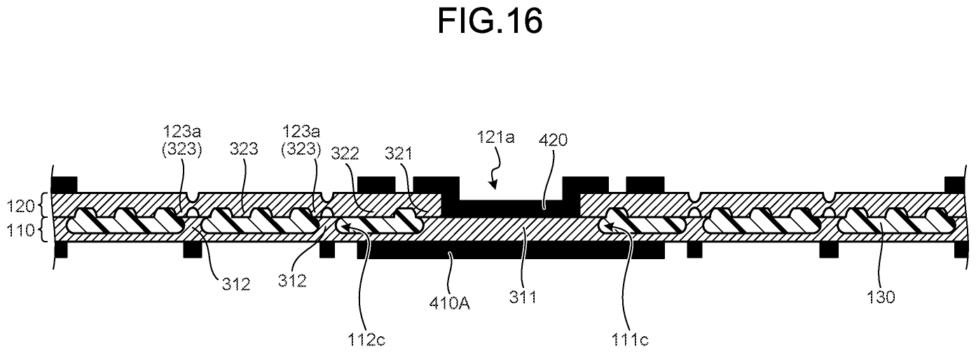

After the intermediate structure is sealed with resin, an etching resist is formed on each of the surfaces of the first frame member 110 and the second frame member 120 (step S105). Specifically, for example, as illustrated in FIG. 16, an etching resist 410A is formed on the side of the lower surface of the first frame member 110 and the etching resist 420 is formed on the side of the upper surface of the second frame member 120. FIG. 16 is a diagram illustrating a specific example of an etching resist forming step. The etching resists 410A and 420 are formed in positions to be left as the die pad 111, the terminals 112, the ground pad 121 and the leads 122. For example, the etching resist 410A is formed in positions of the base 311 and the protrusions 312 to be left as the die pad 111 and the terminals 112, respectively. The etching resist 410A is extended to an outer position with respect to the outer circumference of the base 311 to be left as the extending portion 111d of the die pad 111 and is formed. The etching resist 420 is formed as in the case of the etching resist 420 of the first embodiment.

The first frame member 110 and the second frame member 120 on which such etching resists are formed are immersed in an etching solution and are etched (step S106). Specifically, for example, the first frame member 110 and the second frame member 120 are immersed in an etching solution, such as sulfuric-acid hydrogen peroxide or persulfate, and accordingly given parts that are not covered with the etching resists are dissolved and the frame members are molded into the shape of the lead frame 100.

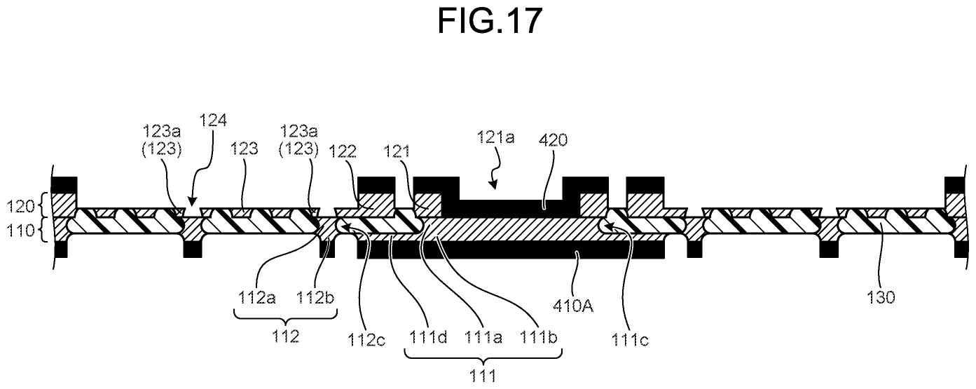

In other words, for example, as illustrated in FIG. 17, the given portions not overlapping the base 311 of the first frame member 110, the area extending to the outer position than the outer circumference of the base 311, and the protrusions 312 are etched and accordingly the die pad 111 and the terminals 112 are formed. Furthermore, for example, the given portions not overlapping the base 321 of the second frame member 120, the upper surface of the base 311, and the protrusions 322 are etched and accordingly the ground pad 121, the leads 122 and the interconnects 123 are formed. The depressed portions that are formed on both end faces of the interlayer connector 123a of the interconnect 123 communicate by etching from the side of the upper surface of the interlayer connector 123a and accordingly the opening 124 is formed. FIG. 17 is a diagram illustrating a specific example of an etching step.

In the area extending to the outer position with respect to the outer circumference of the base 311, the metal portion of the first frame member 110 remains and thus the extending portion 111d is formed. The extending portion 111d is formed such that the extending portion 111d extends to the position corresponding to the lead 122 on the surface of the resin 130. The extending portion 111d increases efficiency of transmission of heat, ultrasound, and load that are transmitted to the lead 122 to join the wire when the semiconductor element that is mounted on the upper surface of the die pad 111 and the leads 122 are connected by wire bonding. In other words, because the extending portion 111d is formed, heat from a heater that heats the leads 122 is efficiently transmitted from a lower side of the leads 122 to the leads 122 via the extending portion 111d. Furthermore, because the extending portion 111d is formed, the leads 122 are supported by the extending portion 111d and ultrasound and load from a wire bonder that pushes the wires against the leads 122 from above the leads 122 are efficiently transmitted to the wires. Wire bonding between the semiconductor element and the leads 122 will be described below.

When etching completes, as in the first embodiment described above, each of the etching resist removing step (step S107) and the electrolytic plating step (step S108) is performed and accordingly the lead frame 100 is completed.

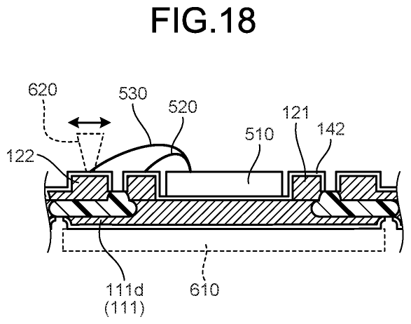

Wire bonding will be described with reference to FIG. 18. FIG. 18 is a diagram illustrating wire bonding. In the process of manufacturing a semiconductor device, after the semiconductor element 510 is joined to the upper surface of the die pad 111, for example, as illustrated in FIG. 18, the semiconductor element 510 and the ground pad 121 are connected by wire bonding and the semiconductor element 510 and the leads 122 are connected by wire bonding. In other words, the ground electrode of the semiconductor element 510 is electrically connected to the plating layer 142 on the ground pad 121 by the wire 520. Furthermore, a signal electrode of the semiconductor element 510 is electrically connected to the plating layer 142 on the lead 122 by a wire 530. The extending portion 111d is positioned in the position corresponding to the lead 122 on the surface of the resin 130 and therefore heat from a heater 610 that heats the lead 122 for joining the wire 530 is efficiently transmitted to the lead 122. Furthermore, because the lead 122 is supported by the extending portion 111d from the lower side, ultrasound and load from a wire bonder 620 that pushes the wire 530 against the lead 122 are efficiently transmitted to the wire 530. As a result, because it is possible to assuredly join the wire 530 to the plating layer 142 on the lead 122, it is possible to increase reliability in connection between the lead 122 and the wire 530.

As described above, the die pad of the lead frame according to the embodiment is formed on the outer circumference of the rising portion (for example, the rising portion 111b) and includes the extending portion (for example, the extending portion 111d) that extends to an outer side with respect to the rising portion along the surface of the resin (for example, the resin 130). Thus, according to the lead frame 100 according to the embodiment, it is possible to increase strength of bonding between the die pad and the sealing resin.

The extending portion according to the embodiment extends to the position corresponding to the lead (for example, the lead 122) on the surface of the resin. Thus, according to the lead frame 100 according to the embodiment, it is possible to increase reliability of connection between the leads and the wires when the semiconductor element and the leads are connected by wire bonding.

Others

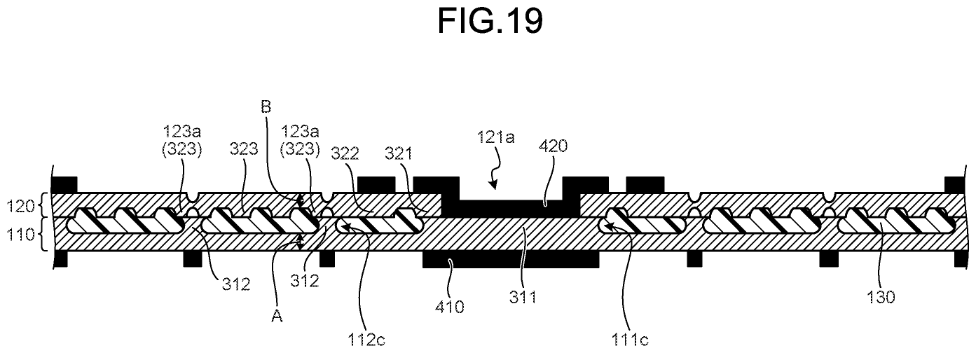

The above-described embodiment presents the example in which the first frame member 110 and the second frame member 120 on which the etching resists are formed are immersed in the etching solution and accordingly portions that are to be etched and that are not covered with the etching resists are dissolved (the etching step, refer to FIG. 8 and FIG. 17). When the thickness of the portions to be etched in the first frame member 110 is smaller than the thickness of portions to be etched in the second frame member 120, the portions to be etched in the first frame member 110 are excessively dissolved and the side surfaces of the buried portion 11a erode. As a result, there is a risk that the shape of the constriction 111c on the side surfaces of the buried portion 111a would be lost. From the viewpoint of keeping the shape of the constriction 111c, as illustrated in FIG. 19, it is preferable that the thickness of a portion A to be etched in the first frame member 110 and the thickness of a portion B to be etched in the second frame member 120 are approximately equal to each other. FIG. 19 is a diagram illustrating an example of the first frame member 110 and the second frame member 120 on which the etching resists are formed.

According to a mode of the lead frame disclosed herein, an effect that it is possible to inhibit the die pad from separating from the resin is achieved.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

Note

(1) A method of manufacturing a lead frame, the method comprising:

molding, from a first metal plate, a first frame member in which a base having a mount surface on which a semiconductor element is to be mounted is sectioned by a first depressed portion;

molding, from a second metal plate, a second frame member in which a plurality of first protrusions are sectioned by a second depressed portion;

layering the second frame member on the first frame member;

filling a space that is formed by the first depressed portion and the second depressed portion with a sealing resin around the base and the first protrusions; and

forming a die pad on the first frame member and forming a lead on the second frame member by etching at least a given portion not overlapping the base and the first protrusions in the first frame member and the second frame member, wherein

the molding the first frame member includes forming, by performing anisotropic etching on the first metal plate, the base having a constriction that is depressed in a direction parallel to the mount surface on a side surface continuous to the mount surface, and

the etching includes forming the die pad including a buried portion that has a side surface covered with the sealing resin and that has the constriction on the side surface; and a rising portion that rises from the sealing resin.

(2) The method according to the note (1), wherein the etching includes forming the die pad having the buried portion, the rising portion and an extending portion that extends to an outer side with respect to the rising portion along a surface of the resin from an outer circumference of the rising portion.

What is claimed is:

1. A lead frame comprising:
a first frame member including a die pad;
a second frame member that is layered on the first frame member and that includes a lead; and
a resin with which a space around the die pad and the lead is filled,
wherein the die pad includes a rising portion and a buried portion,
the rising portion rises from the resin,
the buried portion is buried in the resin and has a mount surface on which a semiconductor element is to be mounted and a side surface that is continuous to the mount surface, and
the side surface is covered with the resin and has a constriction that is depressed in a direction parallel to the mount surface.

2. The lead frame according to claim 1, wherein a bottom of the constriction is positioned in a more inner position in the buried portion than a circumference of the mount surface.

3. The lead frame according to claim 1, wherein the die pad includes an extending portion that is formed on an outer circumference of the rising portion and that extends to an outer side with respect to the rising portion along a surface of the resin.

4. The lead frame according to claim 3, wherein the extending portion extends to a position corresponding to the lead on the surface of the resin.

5. A semiconductor device comprising:
a lead frame;
a semiconductor element that is mounted on the lead frame; and
a sealing resin that seals the semiconductor element,
wherein the lead frame includes
a first frame member including a die pad;
a second frame member that is layered on the first frame member and that includes a lead; and
a resin with which a space around the die pad and the lead is filled,
the die pad includes a rising portion and a buried portion,
the rising portion rises from the resin,
the buried portion is buried in the resin and has a mount surface on which the semiconductor element is mounted and a side surface that is continuous to the mount surface, and
the side surface is covered with the resin and has a constriction that is depressed in a direction parallel to the mount surface.
